(19) United States
(12) Patent Application Publication
(10) Pub. No.: US 2007/0231951 A1
(43) Pub. Date: Oct. 4, 2007

(54) Reducing layer count in semiconductor packages

(76) Inventor: Mahadevan Suryakumar, Gilbert, AZ (US)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/393,071

(22) Filed: Mar. 29, 2006

(51) Int. Cl. H01L 21/00

(52) U.S. Cl. 438/106

(57) ABSTRACT

An embodiment of the present invention is a technique to fabricate a package. Signals are routed in a signal layer on top of a substrate. Contacts are formed between the routed signals. The contacts are connected to a ground layer. A conductive layer is deposited, by surface mounting, on the substrate to connect to the contacts.

### BACKGROUND

1. Field of the Invention

Embodiments of the invention relate to the field of semiconductor, and more specifically, to semiconductor packaging.

2. Description of Related Art

High performance microprocessors such as multi-die packages have extremely high routing density with high speed input/output (I/O) signaling. For example, in a dual die package, the front side bus (FSB) signal routing density is doubled. The high density routing in dual die packages may lead to a number of problems such as increased cross talk noise reducing the voltage margins. Reduced voltage margins may result in significant decrease in the FSB operating frequency.

Existing techniques to route signals in packages have a number of disadvantages. One technique routes the signal in micro-strip configuration. The technique may reduce the number of layers and package cost, but increase the cross talk noise due to tighter packing of package wires. Another technique routes the signals as strip line with ground shielding above and below the routing signal layer to keep the cross talk noise as low as possible. This technique is not cost effective because it adds additional layers to the package.

### BRIEF DESCRIPTION OF THE DRAWINGS

Embodiments of invention may best be understood by referring to the following description and accompanying drawings that are used to illustrate embodiments of the invention. In the drawings:

FIG. 1A is a diagram illustrating a manufacturing system in which one embodiment of the invention can be practiced.

FIG. 1B is a diagram illustrating a system according to one embodiment of the invention.

FIG. 2 is a diagram illustrating a package device according to one embodiment of the invention.

FIG. 3 is a diagram illustrating a substrate according to one embodiment of the invention.

FIG. 4 is a diagram illustrating layout of a top signal layer in the substrate according to one embodiment of the invention.

FIG. 5 is a flowchart illustrating a process to reduce layer count in the substrate according to one embodiment of the invention.

FIG. 6 is a flowchart illustrating a process to deposit the conductive layer according to one embodiment of the invention.

### DESCRIPTION

An embodiment of the present invention is a technique to fabricate a package using external conductive foil to reduce the package layer count while meeting high performance at low cost. Signals are routed in a signal layer on top of a substrate. Contacts are formed between the routed signals. The contacts are connected to a ground layer. A conductive layer is deposited, by surface mounting, on the substrate to connect to the contacts.

In the following description, numerous specific details are set forth. However, it is understood that embodiments of the invention may be practiced without these specific details. In other instances, well-known circuits, structures, and techniques have not been shown to avoid obscuring the understanding of this description.

One embodiment of the invention may be described as a process which is usually depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a program, a procedure, a method of manufacturing or fabrication, etc.

An embodiment of the present invention is a technique to reduce the number of layers in a substrate for semiconductor packages without compromising electrical performance. A top ground layer in the substrate is removed. Instead, an external conductive layer is surface mounted on the substrate with connection to an internal ground layer. The connection to the internal ground layer is made through a number of resist openings formed between the routed signals on the top signal layer. The external conductive layer, therefore, acts like a ground layer to provide a strip line configuration for the top signal layer in the substrate. The strip line configuration with the external conductive layer may deliver performance comparable to a substrate with a top internal ground layer. A reduced layer count in the substrate provides several benefits. The first benefit is that there are more choices for substrate manufacturers. For example, if the number of layers is reduced from 12 to 10, a manufacturer having capability to manufacturer only up to 10-layer substrates may be selected in addition to those having capability to manufacture 12-layer substrates. This may lead to competitive pricing. The second benefit is that the time to manufacture may be reduced or accelerated due to more choices for substrate manufacturers. The third benefit is the reduction in material and design costs associated with the fabrication of substrates with reduced layer count.

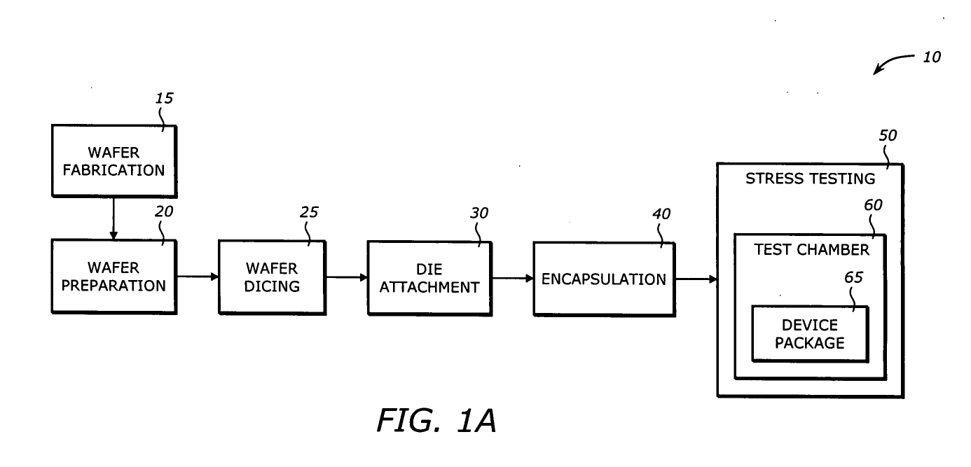

FIG. 1A is a diagram illustrating a manufacturing system 10 in which one embodiment of the invention can be practiced. The system 10 includes a wafer fabrication phase 15, wafer preparation phase 20, a wafer dicing phase 25, a die attachment phase 30, an encapsulation phase 40, and a stress testing phase 50. The system 10 represents a manufacturing flow of a semiconductor packaging process.

The wafer fabrication phase 15 fabricates the wafer containing a number of dice. The individual dice may be any microelectronic devices such as microprocessors, memory devices, interface circuits, etc. The wafer fabrication phase 15 includes typical processes for semiconductor fabrication such as preparation of the wafer surface, growth of silicon dioxide (SiO₂), patterning and subsequent implantation or diffusion of dopants to obtain the desired electrical properties, growth or deposition of a gate dielectric, and growth or deposition of insulating materials, depositing layers of metal and insulating material and etching it into the desired patterns. Typically the metal layers consist of aluminium or copper. The various metal layers are interconnected by etching holes, called “vias,” in the insulating material.

The wafer preparation phase 20 prepares a wafer containing dice for packaging and testing. During this phase, the wafers are sorted after the patterning process. An inspection may be carried out to check for wafer defects. Then, the wafer may be mounted on a backing tape that adheres to the back of the wafer. The mounting tape provides mechanical support for handling during subsequent phases.

The wafer dicing phase 25 dices, cuts, or saws the wafer into individual dice. High precision saw blade and image recognition unit may be used. De-ionized water may be dispensed on the wafer to wash away any residual particles or contaminants during the dicing. Then, the wafer is dried by being spun at high spinning speed.

The die attachment phase 30 attaches the die to a package substrate. The substrate material depends on the packaging type. It may be lead-frame, plastic, or epoxy. The substrate is fabricated to have a reduced layer count by using an external ground layer. The external ground layer may be a conductive layer, such as a copper foil, that is surface mounted on the substrate.

The encapsulation phase 40 encapsulates the die and the substrate. Depending on the packaging type, this may include molding, wire bonding, and solder ball attachment. Underfill material may be dispensed between the die and the substrate. Integrated heat spreader (IHS) may be attached to the die and substrate assembly. The encapsulated assembly of the die and substrate becomes a device package 65 ready to be tested.

The stress testing phase 50 performs one or more tests such as Highly Accelerated Stress Test (HAST) or biased-HAST on the device package under stress conditions. A test chamber 60 may be designed to conduct a stress test. It may have monitoring circuits, measurement circuits, and other data processing equipment. The package 65 is placed in the test chamber 60 subject to the stress test. It may be powered or non-powered. Various stress tests may be performed on the wafer or on the packaged devices 65 at various points of the manufacturing process flow. The tests may follow standards such as Joint Electron Device Engineering Council (JEDEC) standards or military standards. Examples of these tests may include electrostatic discharge (ESD), or human body model (HBM), high temperature operational life (HTOL), thermal shock, temperature cycle, high temperature storage, vibration and mechanical loading, shear testing, and accelerated moisture resistance.

FIG. 1B is a diagram illustrating a system 100 according to one embodiment of the invention. The system 100 represents a mobile communication module. It includes a system on package (SOP) 110, an intermediate frequency processing unit 160, and a base-band processing unit 170.

The SOP 110 represents the front end processing unit for the mobile communication module. It is a transceiver incorporating on-package integrated lumped passive components as well as radio frequency (RF) components. It includes an antenna 115, a duplexer 120, a filter 125, a system-on-chip (SOC) 150, a power amplifier (PA) 180, and a filter 18.

The antenna 115 receives and transmits RF signals. The RF signals may be converted to digital data for processing in subsequent stages. It is designed in compact micro-strip and strip-line for L and C-band wireless applications. The duplexer 120 acts as a switch to couple to the antenna 115 to the receiver and the transmitter to the antenna 115. The filters 125 and 185 are C-band LTCC-strip-line filter or multilayer organic lumped-element filter at 5.2 GHz and narrowband performance of 200 MHz suitable for the Institute of Electrical and Electronic Engineers (IEEE) 802.11 wireless local area network (WLAN). The SOC 150 includes a low noise amplifier (LNA) 130, a down converter 135, a local voltage controlled oscillator (VCO) 140, an up converter 171, and a driver amplifier 175. The LNA 130 amplifies the received signal. The down converter 135 is a mixer to convert the RF signal to the IF band to be processed by the IF processing unit 160. The up converter 171 is a mixer to convert the IF signal to the proper RF signal for transmission. The VCO 140 generates modulation signal at appropriate frequencies for down conversion and up conversion. The driver amplifier 175 drives the PA 180. The PA 180 amplifies the transmit signal for transmission.

The IF processing unit 160 includes analog components to process IF signals for receiving and transmission. It may include a band-pass filter and a low pass filter at suitable frequency bands. The filter may provide base-band signal to the base-band processing unit 170. The base-band processing unit 170 may include an analog-to-digital converter (ADC) 172, a digital-to-analog converter (DAC) 174, and a digital signal processor (DSP) 176. The ADC 172 and the DAC 174 are used to convert analog signals to digital data and digital data to analog signal, respectively. The DSP 176 is a programmable processor that may execute a program to process the digital data. The DSP 176 may be packaged using Flip-Chip Ball Grid Array (FCBGA) packaging technology or any other suitable packaging technologies. The DSP 176 may be manufactured according to the manufacturing flow 10 shown in FIG. 1A. It may be the device package 65. The base-band processing unit 170 may also include memory and peripheral components. The DSP 176 may, therefore, be coupled to the front end processing unit via the IF processing unit 160 and/or the base-band processing unit 170 to process the digital data.

The SOP 110 may be a multi-layer three-dimensional (3D) architecture for a monolithic microwave integrated circuit (MMIC) with embedded passives (EP) technology. It may be implemented using Low Temperature Co-fired Ceramics (LTCC) and organic-based technologies. The 3D architecture may include multiple layers include a layer 117 to implement the antenna 115, layers 122, 124, and 186 for the filters 125 and 185, and layer 188 for the SOC 150 and the passive components using EP technology. Typically, the packaging technology involves embedded passives with multiple layers.

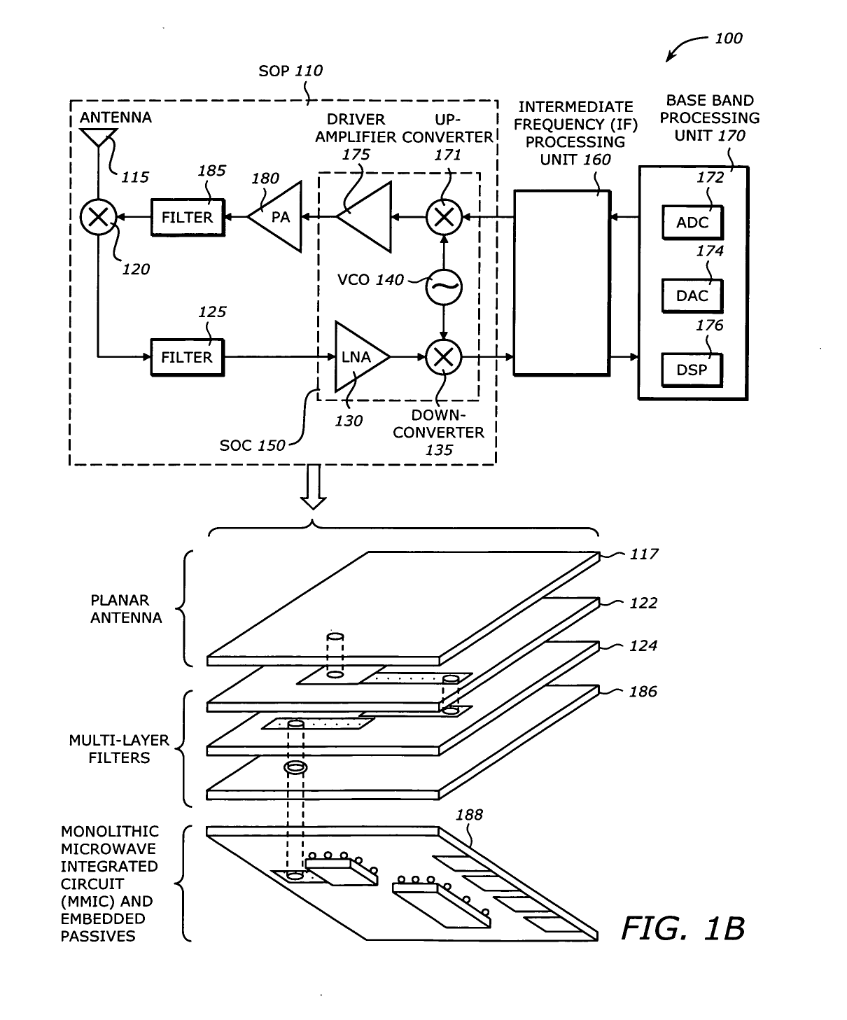

FIG. 2 is a diagram illustrating the package device 65 or 176 shown in FIG. 1A and FIG. 1B, respectively, according to one embodiment of the invention. The package device 65/176 includes a substrate 210, a die 220, an underfill 230, an integral heat spreader (IHS) 250, and a conductive layer 260.

The substrate 210 is a package substrate that provides support for the die 220. The substrate 210 may be polymer or a composite. The substrate 210 contains a reduced number of internal layers. The substrate 210 may be selected for any suitable packaging technologies including Ball Grid Array (BGA), Pin Grid Array (PGA), or Land Grid Array (LGA). The substrate 210 may be attached to a number of solder balls 215. The solder balls 215 allow attachment of the package device 165 to a circuit board or to any other mounting component. The die 220 is any semiconductor die. It may have a microelectronic device such as a microprocessor, a memory, an interface chip, an integrated circuit, etc. The die 220 is attached to the substrate 110 by a number of solder bumps 225. The bumps 225 provide contact with the contact pads on the substrate. The bumps 225 may be fabricated using any standard manufacturing or fabrication techniques such as the controlled collapse chip connect (C4) technique. The underfill 230 is dispensed between die 220 and the substrate 210 to strengthen the attachment of die 220 to the substrate 210 to help prevent the thermal stresses from breaking the connections between die 220 and the substrate 210. The stresses may be caused by the difference between the coefficients of thermal expansion of die 220 and the substrate 210. The underfill 230 may contain filler particles suspended in an organic resin. The size of the filler particles are typically selected according to a gap between the die 220 and the substrate 210, e.g., the filler particles have a diameter about one third the size of the gap. Generally, the composition and concentration of filler particles are selected to control the coefficient of thermal expansion and the shrinkage of the underfill 230.

The IHS 250 may house or cover the die 220 on the substrate 210. It may include a flat surface and supporting walls on both or four sides of the die 220. During operation, the die 220 may generate heat. The heat may be transferred to the IHS 250 through a thermal interface material (TIM) 240. The TIM 240 may be located, or interposed, between the bottom surface of the IHS 250 and the top surface of the die 220 to encapsulate the cover assembly 260. It may be attached to a heat generating device, such as the die 220, to transfer the heat to a heat spreader or a heat sink or any another heat dissipating device. The TIM 240 may be made of thermal grease, phase change material (PCM), pads, films, and gels, or any thermally conducting material such as Sn solder, or tungsten, or a combination of such materials, which also show good adhesion (e.g., wetting) with the IHS 250 and the die 220.

The conductive layer 260 is deposited, by surface mounting, on top of the substrate 210. It may be a conductive foil made of a conductive material such as metal. Any metal having good conductivity, such as copper, may be used. The conductive layer 260 may have a thickness ranging from a few microns (μm) to 20 microns. The conductive layer 260 acts as a ground layer external to the substrate 210. Accordingly, the number of layers in the substrate 210 may be reduced, leading to several economic advantages while providing performance comparable to a substrate with non-reduced layer count.

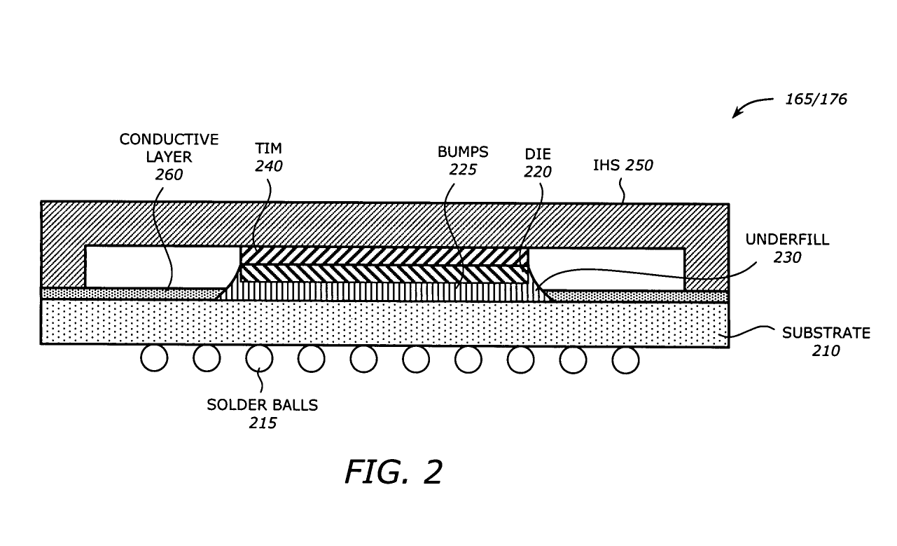

FIG. 3 is a diagram illustrating the substrate 210 shown in FIG. 2 according to one embodiment of the invention. The substrate 210 has a top signal layer 310, signal layers 320, ground layers 330, power layers 340, a removed redundant power layer 345, and a solder mask layer 350.

The top signal layer 310 has routed signals and contacts 360 between the routed signals. The contacts 360 are connected to a ground layer inside the substrate 210 such as any of the ground layers 330 through the ground floods 370 in the top signal layer 310. The contacts 360 may be solder bumps or solder resist openings that are placed on the ground floods 370. The ground floods 370 are groups of ground points that are added between the signal routes at multiple points of the routes.

The signal layers 320 are layers that contain signal traces like the top layer 310 except that they do not have ground floods connected to contacts. The ground layers 330 are layers connected to the ground supply. The ground layers 330 typically sandwich the signal layers to form a strip line configuration. The power layers 340 are layers that are connected to the voltage supply for the package. The removed redundant power layer 345 is a redundant power layer that is removed or not used because it is not necessary.

The solder mask layer 350 is deposited on the top signal layer 310 to protect the top signal layer 350 and exposes the contacts 360. When the conductive layer 260 is deposited on the substrate 210, it is surface mounted on the solder mask layer 350 and is connected to the contacts 360 so that it is electrically connected to a ground layer. In essence, the conductive layer 260 acts as a ground layer that is external to the substrate 210. Therefore, the conductive layer 260, the top signal layer 310, and one of the ground layers 330 below the top signal layer 310 form a strip line configuration. This strip line configuration is unbalanced because the conductive layer is not exactly the same as an internal ground layer. The unbalanced strip line may be made close to a balanced strip line if the contacts 360 or the ground floods 370 are properly placed and sized. For example, the solder bumps may be made very small. The unbalanced strip line configuration formed by the external conductive layer 260 and the top signal layer 310 still has the desirable effects of a strip line configuration. It may reduce the coupling between the package wires or stray capacitances, and lower the crosstalk noise.

By using the conductive layer 260 as an external ground layer and not using the redundant power layer 345, the number of layers in the substrate is reduced by two. For example, a typical dual die microprocessor substrate has 12 layers. With this design, the number of layers is reduced to 10. Detailed electrical analysis with external conductive foil shows that the 10-layer design has performance comparable to the 12-layer design. The advantages of the reduced layer count include lower cost substrate fabrication, reduced manufacturing time, and more choices of substrate vendors.

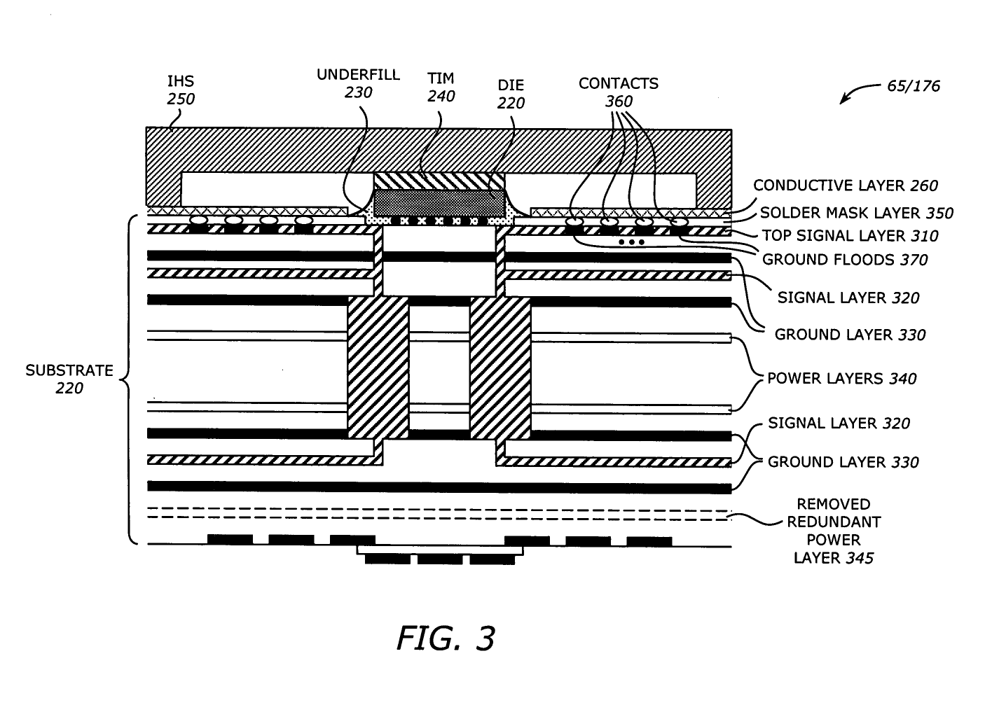

FIG. 4 is a diagram illustrating layout of the top signal layer 310 shown in FIG. 3 in the substrate according to one embodiment of the invention.

The top signal layer 310 has signal traces routed according to some routing paths. It has fan-out regions and break-out regions such as fan-out regions 410 and 420 and a break-out region 430. The contacts or the resist openings 360 are formed at the fan-out regions 410 and 420 and the break-out region 430 to simplify the routing and optimize the ground performance.

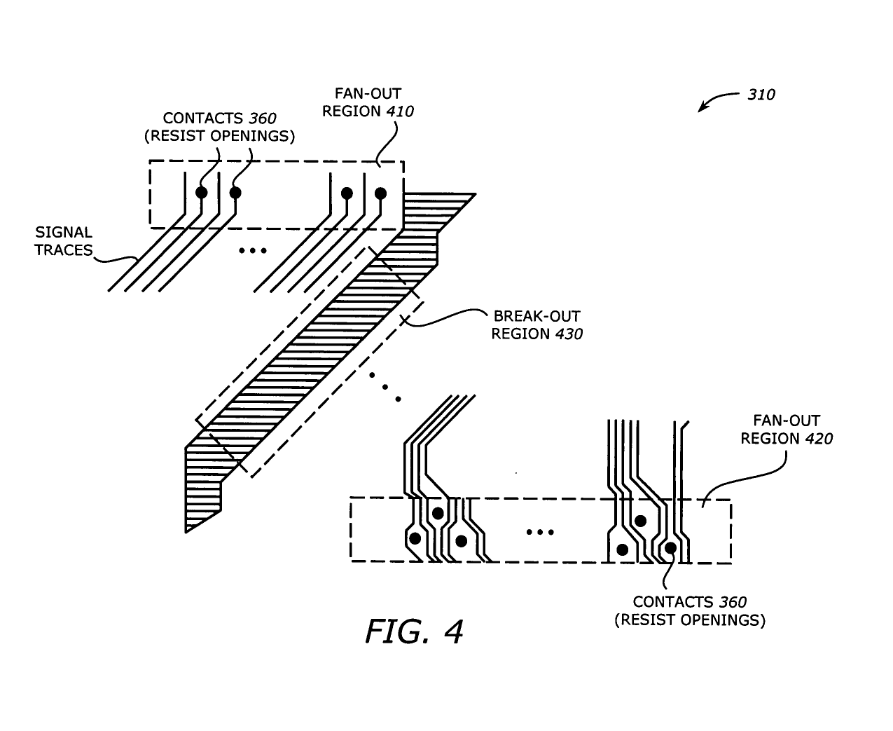

FIG. 5 is a flowchart illustrating a process 500 to reduce layer count in the substrate according to one embodiment of the invention.

Upon START, the process 500 routes signals in a signal layer on top of a substrate (Block 510). Next, the process 500 forms contacts between the routed signals (Block 520). The contacts are connected to a ground layer in the substrate. The contacts are formed as solder bumps or solder resist openings between the routed signals. The resist openings are formed at break-out and/or fan-out regions on the signal layer.

Then, the process 500 deposits a solder mask layer on the signal layer on top of the substrate (Block 530). The solder mask layer exposes the contacts or the resist openings. Next, the process 500 deposits a conductive layer on the substrate to connect to the contacts (Block 540). Then, the process 500 removes a redundant power layer in the substrate (Block 550). The process 500 does not form the redundant power layer because it is not needed. The process 500 is then terminated.

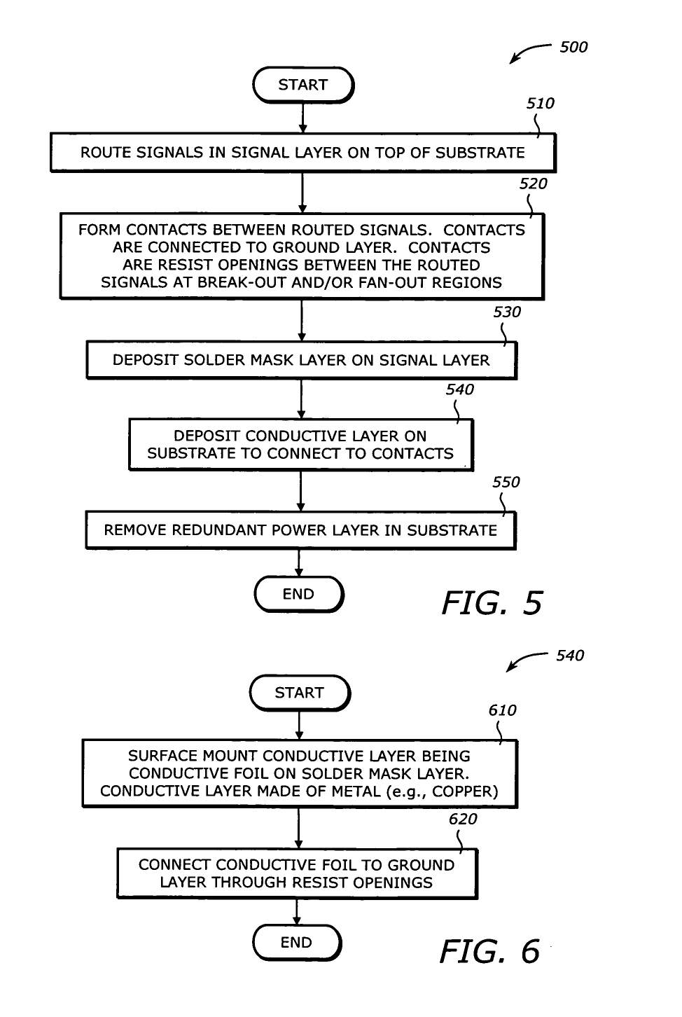

FIG. 6 is a flowchart illustrating the process 540 to deposit the conductive layer according to one embodiment of the invention.

Upon START, the process 540 surface mounts the conductive layer being a conductive foil on the solder mask layer (Block 610). The conductive layer is a conductive foil made of a metal such as copper. Next, the process 540 connects the conductive foil to the ground layer through the resist openings (Block 620). The process 540 is then terminated.

Embodiments of the invention have been described with a package having a conductive foil deposited on the substrate. The conductive foil acts as a ground layer but placed externally to the substrate. The signal layer together with the conductive foil and a ground layer inside the substrate essentially form an unbalanced strip line. The conductive foil shields the signals in the signal layer and therefore reduces the coupling between package wires and lowers the crosstalk noise. The substrate therefore may be fabricated with reduced layer count with comparable performance, leading to cost efficient packaging.

While the invention has been described in terms of several embodiments, those of ordinary skill in the art will recognize that the invention is not limited to the embodiments described, but can be practiced with modification and alteration within the spirit and scope of the appended claims. The description is thus to be regarded as illustrative instead of limiting.

What is claimed is:

1. A method comprising:
routing signals in a signal layer on top of a substrate;
forming contacts between the routed signals, the contacts being connected to a ground layer; and
depositing an external conductive layer on the substrate to connect to the contacts.

2. The method of claim 1 further comprising:
depositing a solder mask layer on the signal layer.

3. The method of claim 2 wherein forming contacts comprises:
forming resist openings as the contacts between the routed signals.

4. The method of claim 3 wherein depositing the external conductive layer comprises:
surface mounting the external conductive layer being a conductive foil on the solder mask layer; and
connecting the conductive foil to the ground layer through the resist openings.

5. The method of claim 3 wherein forming the resist openings comprises:
forming the resist openings at break-out and/or fan-out regions.

6. The method of claim 1 further comprising:
removing a redundant power layer in the substrate.

7. The method of claim 1 wherein the external conductive layer is made of metal.

8. An apparatus comprising:
a substrate comprising a signal layer at top of the substrate, the signal layer having routed signals and contacts between the routed signals, the contacts being connected to a ground layer; and
an external conductive layer deposited on the substrate to connect to the contacts.

9. The apparatus of claim 8 wherein the substrate further comprises:
a solder mask layer deposited on the signal layer.

10. The apparatus of claim 9 wherein the contacts are formed by resist openings between the routed signals.

11. The apparatus of claim 10 wherein the external conductive layer is a conductive foil surface mounted on the solder mask layer, the conductive foil being connected to the ground layer through the resist openings.

12. The apparatus of claim 10 wherein the resist openings are formed at break-out and/or fan-out regions.

13. The apparatus of claim 8 wherein a redundant power layer in the substrate is removed.

14. The apparatus of claim 10 wherein the external conductive layer is made of metal.

15. A package comprising:
a substrate comprising a signal layer at top of the substrate, the signal layer having routed signals and contacts between the routed signals, the contacts being connected to a ground layer;
a die attached to the substrate;
an integrated heat spreader (IHS) attached to the substrate and encapsulating the die; and
an external conductive layer deposited on the substrate to connect to the contacts.

16. The package of claim 15 wherein the substrate further comprises:
a solder mask layer deposited on the signal layer.

17. The package of claim 16 wherein the contacts are formed by resist openings between the routed signals.

18. The package of claim 17 wherein the external conductive layer is a conductive foil surface mounted on the solder mask layer, the conductive foil being connected to the ground layer through the resist openings.

19. The package of claim 17 wherein the resist openings are formed at break-out and/or fan-out regions.

20. The package of claim 15 wherein a redundant power layer in the substrate is removed.

21. The package of claim 17 wherein the external conductive layer is made of metal.

22. A system comprising:
a front end processing unit to receive and transmit a radio frequency (RF) signal, the RF signal being converted to digital data; and
a digital processor coupled to the front end processing unit to process the digital data, the digital processor being packaged in a package, the package comprising:
a substrate comprising a signal layer at top of the substrate, the signal layer having routed signals and contacts between the routed signals, the contacts being connected to a ground layer,
a die attached to the substrate,
an integrated heat spreader (IHS) attached to the substrate and encapsulating the die, and
an external conductive layer deposited on the substrate to connect to the contacts.

23. The system of claim 22 wherein the substrate further comprises:
a solder mask layer deposited on the signal layer.

24. The system of claim 23 wherein the contacts are formed by resist openings between the routed signals.

25. The system of claim 24 wherein the external conductive layer is a conductive foil surface mounted on the solder mask layer, the conductive foil being connected to the ground layer through the resist openings.

26. The system of claim 24 wherein the resist openings are formed at break-out and/or fan-out regions.

27. The system of claim 22 wherein a redundant power layer in the substrate is removed.

28. The system of claim 24 wherein the external conductive layer is made of metal.
